(19) United States
(12) Patent Application Publication
(10) Pub. No.: US 2026/0219567 A1
(43) Pub. Date: Jul. 30, 2026

(54) PHOTORESIST

(71) Applicants: TAIWAN SEMICONDUCTOR MANUFACTURING COMPANY, LTD., Hsinchu (TW); NATIONAL TSING HUA UNIVERSITY, Hsinchu City (TW)

(72) Inventors: Jui-Hsiung LIU, Taipei City (TW); Burn Jeng LIN, Hsinchu City (TW); Pei-Chi WU, Chiayi County (TW); Chun-Tai HUANG, Hsinchu City (TW); Kuei-Shun CHEN, Hsinchu City (TW); An-Ren ZI, Hsinchu City (TW); Shi-Cheng WANG, Tainan City (TW)

(73) Assignees: TAIWAN SEMICONDUCTOR MANUFACTURING COMPANY, LTD., Hsinchu (TW); NATIONAL TSING HUA UNIVERSITY, Hsinchu City (TW)

(21) Appl. No.: 19/036,714

(22) Filed: Jan. 24, 2025

(51) Int. Cl. G03F 7/004; G03F 7/20

(52) U.S. Cl. CPC G03F 7/0042; G03F 7/2004

(57) ABSTRACT

A photoresist composition comprises a first photoresist. The first photoresist has a formula (a1) or a formula (a2):

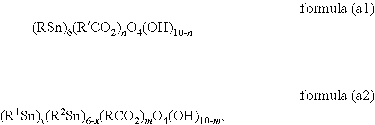

and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e):

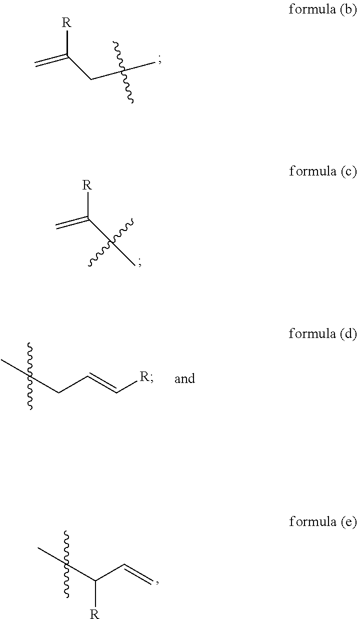

in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, patterns are formed on the semiconductor wafer which incorporates minimum feature sizes under a resolution or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic view of an EUV lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 1C is a sectional view of a EUV mask constructed in accordance with some embodiments of the present disclosure.

FIG. 2 is a flow chart diagram of a method of fabricating a semiconductor device using a photoresist layer according to various aspects of the present disclosure.

FIGS. 3, 4, 5A and 5B illustrate fragmentary cross-sectional side views of the semiconductor device corresponding to the flow chart diagram in FIG. 2 in accordance with various aspects of the present disclosure.

FIG. 6 is a plot with an EUV contrast curve involving a function of exposure dose for the photoresist layer formed by the first photoresist and the second photoresist with the formulae (a3) or (a4).

FIGS. 7, 8, 9, 10, 11, 12, 13, 14 and 15A illustrate perspective views of additional fabrication processes in the formation of a semiconductor device in accordance with some embodiments of the present disclosure.

FIGS. 15B, 16, 17 and 18 illustrate cross-sectional views of additional fabrication processes in the formation of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

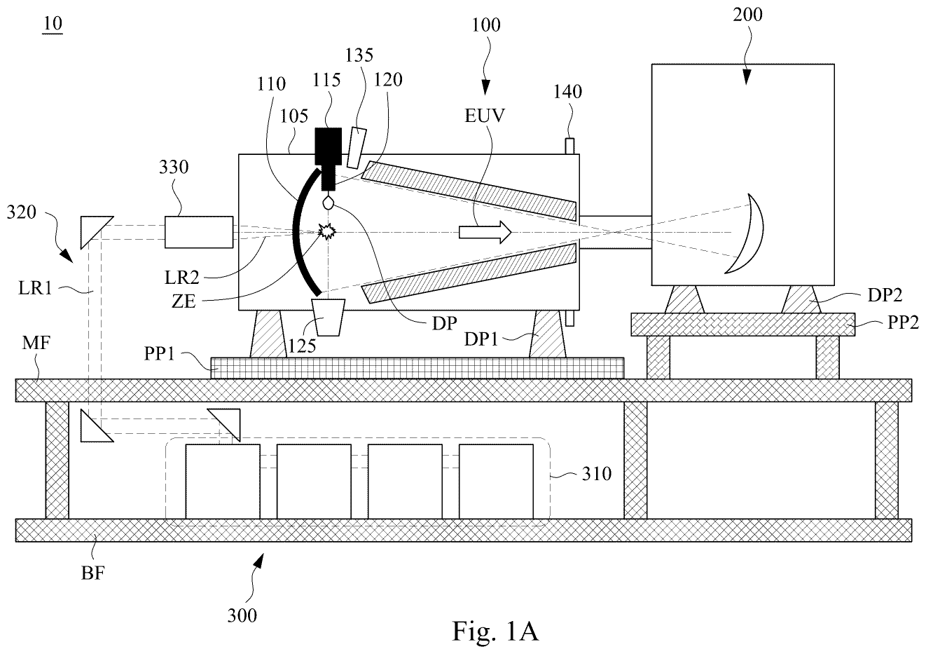

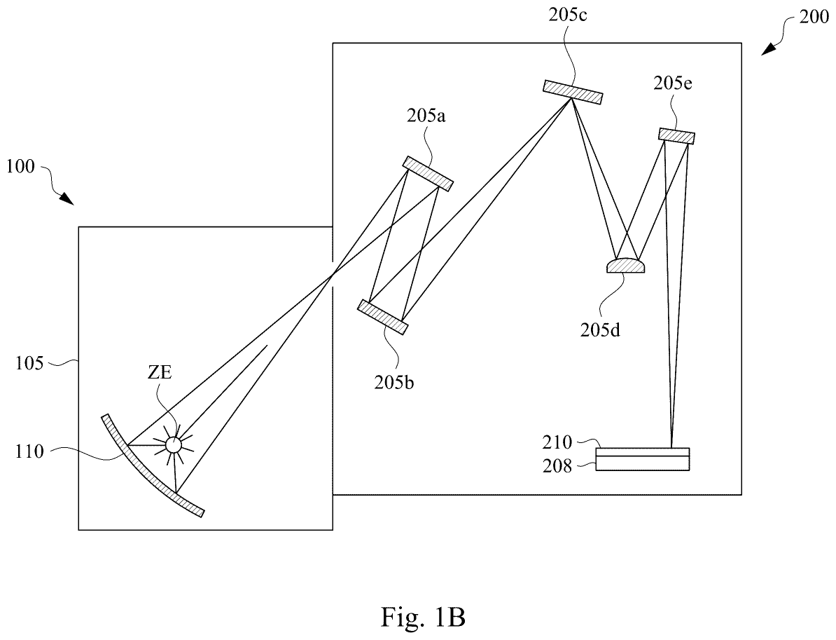

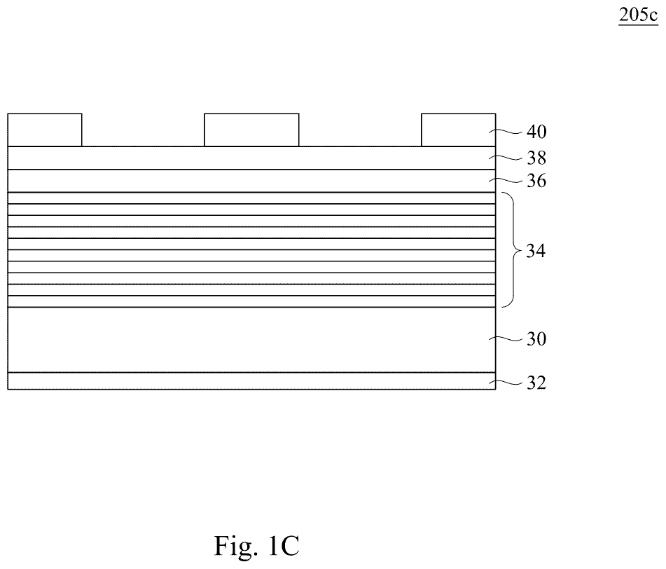

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by an EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates an EUV light with a wavelength centered at about 13.5 nm. Accordingly, the radiation source 100 is also referred to as EUV radiation source 100.

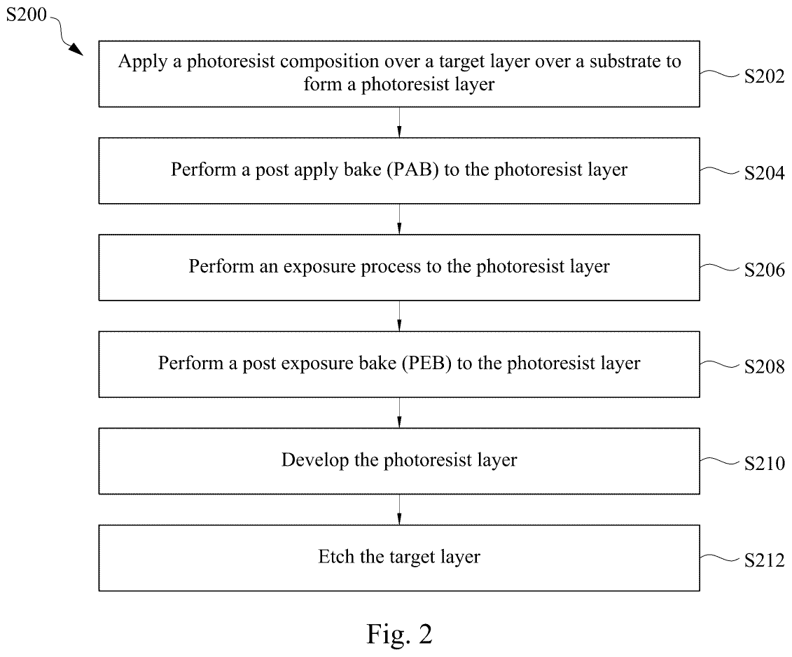

The present disclosure provides a novel photoresist composition including a first photoresist composition having a formula (a1) or a formula (a2). By applying the novel photoresist composition to form the photoresist layer, the photoresist layer can have improved photosensitive property toward the EUV light. Further, the photoresist layer can provide low line width roughness (LWR) and low line edge roughness (LER) and high solid content. The various aspects of the present disclosure will be discussed below in greater detail with reference to FIGS. 1A-18. First, an EUV lithography system will be discussed below with reference to FIGS. 1A, 1B and 1C. Next, the details of the novel photoresist and the lithography process employing the photoresist will be discussed with reference to FIGS. 2-18.

The advanced lithography process, method, and materials described in the current disclosure can be used in many applications, including fin-type field effect transistors (FinFETs), gate-all-around (GAA) FETs. For example, the fins may be patterned to produce a relatively close spacing between features, for which the above disclosure is well suited. In addition, spacers used in forming fins of FinFETs can be processed according to the above disclosure. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1C, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength. In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. A droplet generator 115 is turned on to eject the target droplets DP toward the zone of excitation ZE in front of the collector 110. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 1C. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 1C, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: Actium, Radium, Tellurium, Zinc, Copper, and Aluminum.

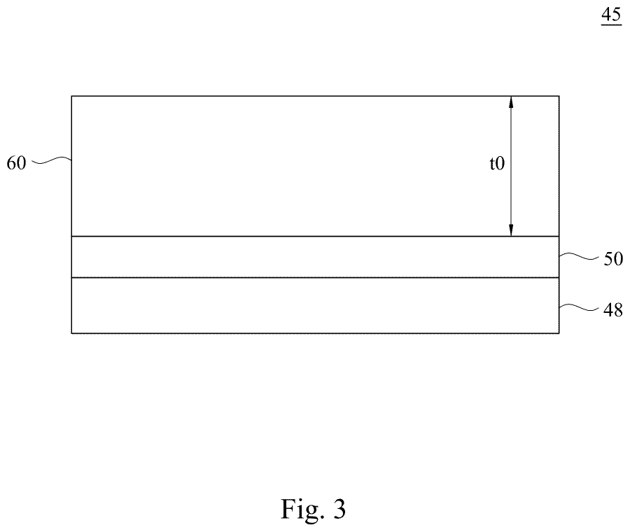

FIG. 2 is a flow chart diagram of a method S200 of fabricating a semiconductor device 45 using a photoresist layer according to various aspects of the present disclosure. FIGS. 3-5B illustrate fragmentary cross-sectional side views of the semiconductor device 45 corresponding to the flow chart diagram in FIG. 2 in accordance with various aspects of the present disclosure. Referring to block S202 of FIG. 2 and to FIG. 3, a photoresist composition is applied over a target layer 50 over a substrate 48 to form a photoresist layer 60. The semiconductor device 45 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors.

In some embodiments, the substrate 48 is a silicon substrate doped with a p-type dopant such as boron (for example a p-type substrate). Alternatively, the substrate 48 could be another suitable semiconductor material. For example, the substrate 48 may be a silicon substrate that is doped with an n-type dopant such as phosphorous or arsenic (an n-type substrate). The substrate 48 could include other elementary semiconductors such as germanium and diamond. The substrate 48 could optionally include a compound semiconductor and/or an alloy semiconductor. Further, the substrate 48 could include an epitaxial layer (epi layer), may be strained for performance enhancement, and may include a silicon-on-insulator (SOI) structure.

In some embodiments, the substrate 48 is substantially conductive or semi-conductive. The electrical resistance may be less than about 103 ohm-meter. In some embodiments, the substrate 48 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 48 may contain Ti, Al, Co, Ru, TiN, WN₂, or TaN.

In some other embodiments, the substrate 48 contains a dielectric material with a dielectric constant in a range from about 1 to about 40. In some other embodiments, the substrate 48 contains Si, metal oxide, or metal nitride, where the formula is MX_{b}, wherein M is a metal or Si, and X is N or O, and wherein “b” is in a range from about 0.4 to 2.5. For example, the substrate 48 may contain SiO₂, silicon nitride, aluminum oxide, hafnium oxide, or lanthanum oxide.

The target layer 50 can be patterned via a lithography process and as such may also be referred to as a patternable layer or target layer. In an embodiment, the target layer 50 includes a dielectric material, such as silicon oxide or silicon nitride. In another embodiment, the target layer 50 includes metal. In yet another embodiment, the target layer 50 includes a semiconductor material.

In some embodiments, the target layer 50 has different optical properties than photoresist. For example, the target layer 50 has a different n, k, or T value from photoresist. In some embodiments, the target layer 50 and the overlying photoresist layer have different etching resistance. In some embodiments, the target layer 50 contains an etching resistant molecule. It is understood that the substrate 48 and the target layer 50 may each include additional suitable material compositions in other embodiments.

The photoresist layer 60 may be formed by a spin-coating process. In some embodiments, the photoresist layer 60 can be spin coated on the target layer 50 on the substrate 48. In many instances, the substrate 48 when in the form of a wafer can have a diameter of 1-inch (25 mm); 2-inch (51 mm); 3-inch (76 mm); 4-inch (100 mm); 5-inch (130 mm) or 125 mm (4.9 inch); 150 mm (5.9 inch, usually referred to as “6 inch”); 200 mm (7.9 inch, usually referred to as “8 inch”); 300 mm (11.8 inch, usually referred to as “12 inch”); or 450 mm (17.7 inch, usually referred to as “18 inch”); for example. For example, a composition of the photoresist layer 60 is placed (dispensed) on the substrate 48. In some embodiments, the photoresist layer 60 has a thickness t0 in a range from 20 nm to 40 nm, such as about 20 nm to about 30 nm.

In some embodiments, the photoresist composition of the photoresist layer 60 can include a first photoresist. In some embodiments, the first photoresist can be a carboxylate-containing 6-tin cluster having a formula (a1) or a formula (a2) below.

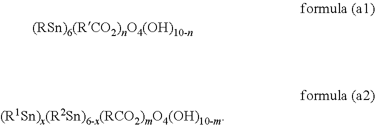

In some embodiments, x is an integer from 0 to 6, and n is an integer from 0 to 6. In some embodiments, in the formulae (a1), each of R and R′ may individually be H, n-CₙH₂ₙ₊₁, i-CₙH₂ₙ₊₁, t-CₙH₂ₙ₊₁ (in which n can be from 1 to 5), or formulae (b) to (e) below.

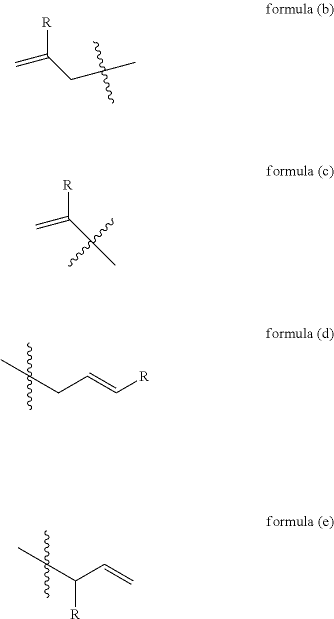

R in the formulae (b) to (e) can be a moiety including H, n-CₙH₂ₙ₊₁, i-CₙH₂ₙ₊₁, t-CₙH₂ₙ₊₁ (in which n can be from 1 to 5). The first photoresist can be capable of forming the photoresist layer 60 that has a smooth surface area with a root mean square (RMS) surface roughness of less than about 0.50 nm. For example, the first photoresist can have the formula (a1), such as Sn₆(C₂H₃)₆(C₄H₉CO₂)₃(OH)₇O₄, with an RMS of about 0.4 nm to about 0.55 nm, such as about 0.51 nm. For example, the first photoresist can have the formula (a1), such as Sn₆(C₃H₅)₃(n-C₄H₉)₃O₄(CH₃CO₂)₅(OH)₅, with an RMS of about 0.2 nm to about 0.4 nm, such as about 0.28 nm. The first photoresist can provide improved photosensitivity toward e-beam and EUV light sources. The first photoresist can provide high solid content for the photoresist layer 60 with high stability and high stable in air. For example, after a subsequent exposure process, the exposed photoresist layer 60 can include SnO₂, which is high stability and high stable in air. The first photoresist can provide high resolution EUV pattern with small EUV doses. For example, the pattern can have a low half-pitch (HP), such as about 20 nm under low exposure dose of the EUV radiation, such as about 60 to about 80 mJ/cm², such as about 76 mJ/cm².

In some embodiments, the photoresist composition of the photoresist layer 60 may further include a solvent. The first photoresist is dissolved in the solvent. The solvent includes an appropriate organic solvent for an adjustment of its viscosity. Such organic solvent includes, but is not limited to, 4-methyl-2-pentanol. In some embodiments, the first photoresist may be in an amount from about 1.5 weight percentage (wt %) to about 2.0 wt % of a total solid weight of the photoresist composition. In some embodiments, the photoresist composition can be heated in duration of about 12 hours and applied to the target layer 50 at a rotation speed of about 1200±100 rpm for about 10±10 seconds at first and then at a rotation speed of about 1600±100 rpm for about 25±10 seconds.

In some embodiments where the first photoresist is represented by the formula (a1), the first photoresist can be synthesized by a reaction shown in the following general reaction scheme 1-1.

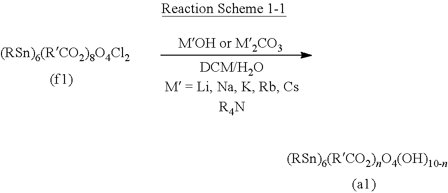

In the Reaction Scheme 1-1, a first reactant is represented by a formula (f1):

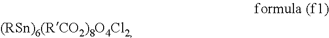

in which each of R and R′ in the formula (f1) may individually be H, n-CₙH₂ₙ₊₁, i-CₙH₂ₙ₊₁, t-CₙH₂ₙ₊₁ (in which m can be from 1 to 5), or formulae (b) to (e) as discussed above, and R of R₄N may be an alkyl group having 1 to 4 carbon atoms. In the reaction scheme 1-1, one equivalent of the first reactant can be treated with 2 to 9 equivalent of M′OH or M′₂CO₃ in a solvent including Dichloromethane (DCM), H₂O, or a combination thereof to form the first photoresist having the formula (a1).

In some embodiments where the first photosensitive is represented by the formula (a2), the first photoresist can be synthesized by a reaction shown in the following general reaction scheme 1-2:

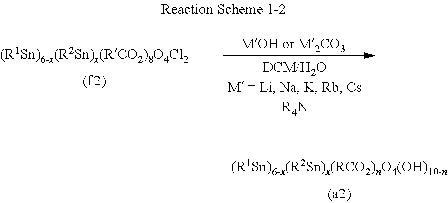

In the Reaction Scheme 1-2, a second reactant is represented by a formula (f2):

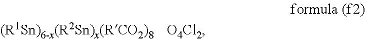

in which R¹ and R² in the formula (f2) may individually be H, n-CₙH₂ₙ₊₁, i-CₙH₂ₙ₊₁, t-CₙH₂ₙ₊₁ (in which n can be from 1 to 5), or formulae (b) to (e) as discussed above, and R of R₄N may be an alkyl group having 1 to 4 carbon atoms. In the reaction scheme 1-2, one equivalent of the first reactant can be treated with 2 to 9 equivalent of M′OH or M′₂CO₃ in a solvent including Dichloromethane (DCM), H₂O, or a combination thereof to form the first photoresist having the formula (a1). The product in the reaction scheme 1-1 and the product in the reaction scheme 1-2 can be determined using thermogravimetric analysis (TGA), element analysis (EA) and nuclear magnetic resonance (NMR) to verify the formation of the formulae (a1) and (a2).

In some embodiments, the photoresist composition of the photoresist layer 60 may be a blend or mixture. In other words, the photoresist composition includes a plurality of photoresists each have a composition different from one another. For example, the photoresist composition may further include a second photoresist mixed with the first photoresist. In some embodiments, the second photoresist can be a hydroxylated tin cluster having a formula (a3) or a formula (a4) below.

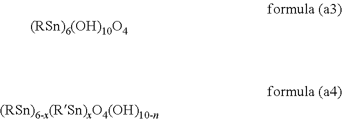

In some embodiments, in the formula (a4), x is an integer from 0 to 6, and n is an integer from 0 to 6. In some embodiments, in the formulae (a3) and (a4), each of R and R′ may individually be H, n-CₙH₂ₙ₊₁, i-CₙH₂ₙ₊₁, t-CₙH₂ₙ₊₁ (in which n can be from 1 to 5), or formulae (b) to (e) as discussed above. For example, the photoresist layer 60 formed by the mixture of the first photoresist (e.g., Sn₆(C₃H₅)₆O₄(CH₃COO)₆(OH)₄ and the second photoresist (e.g., (n-BuSn)₆O₄(OH)₁₀) can have an improved RMS of about 0.21±1 nm in case the weight ratio of the first photoresist and the second photoresist is about 1:1.

The second photoresist with the formulae (a3) and (a4) can be beneficial for providing improved washed-away ability in a subsequent developing step even after undergoing a vigorous post-exposure bake (PEB) step which may be performed at a high temperature. In some embodiments, a wight ratio of the second photoresist to the first photoresist can be in a range from about 10 to about 0.1.

In some other embodiments, the photoresist composition may include a third photoresist mixed with the first photoresist. In some embodiments, the third photoresist can be a 6-Sn cluster having a formula (a5):

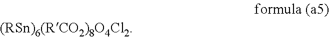

In the formula (a5), each of R and R′ individually may be one of formulae (h1) to (h8):

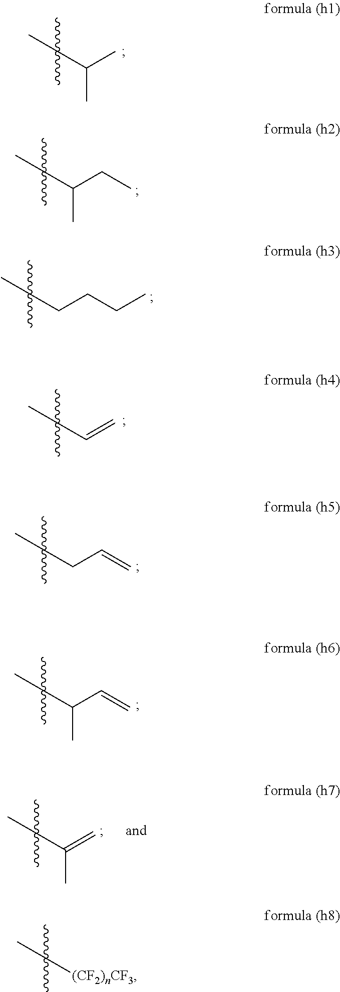

and n in the formula (h8) is 0 to 2. The third photoresist with the formula (a5) can provide improved line, edge, and space character with a low half-pitch (HP), such as about 14 nm under low exposure dose of the EUV radiation, such as about 20 to about 30 mJ/cm² while the third photoresist with the formula (a5) fails to form thick film after the EUV exposure. For example, the third photoresist may form a film having a thickness of less than about 10 nm after the EUV exposure. By mixing the first photoresist having the formula (a1) or (a2) with the third photoresist having the formula (a5) to form the photoresist composition, the photoresist layer 60 can have improved line edge roughness (LER), line width roughness (LWR) properties and the photoresist layer 60 can have a large thickness, such as greater than about 15 nm. In some embodiments, a weight ratio of the first photoresist to the third photoresist is in a range from about 10 to about 0.1. In some embodiments where the photoresist layer 60 is formed by the first photoresist and the third photoresist, after a subsequent exposure process, the exposed photoresist layer can include SnOₓCl_{y}, in which 2x+y=4, instead of SnO₂. The photoresist layer 60 In some embodiments, the formula (a5) can be

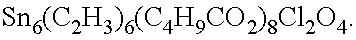

In some other embodiments, the photoresist composition may include a fourth photoresist mixed with the first photoresist. The fourth photoresist can be a metal-containing compound such as a metal triflate salt. For example, the fourth photoresist can have a formula (a6): M(OTf)ₙ formula (a6) in which M can be a metal such as Zn, Sn, In, or Sc, and n is an integer of 1 to 4. In other words, the second photoresist can be Zn(OTf)₂, Sn(OTf)₂, In(OTf)₃, or Sc(OTf)₃. The second photoresist with the formula (a6) can provide improved pattern resolution while the energy doses in a subsequent exposure process is slightly increased or not increased. In some embodiments, a weight ratio of the fourth photoresist to the first photoresist is in a range from about 0.05 to about 0.20. Using the mixture of the first photoresist and the fourth photoresist such as Sn(OTf)₂ as the photoresist composition to form the photoresist layer 60 and exposing the photoresist layer 60 to the exposure source such as e-beam can achieve a half-pitch (HP) of about 20 nm or about 15 nm.

Referring to block S204 of FIG. 2 and to FIG. 3, a post apply bake (PAB) (or soft bake) can be performed to the photoresist layer 60. For example, the photoresist layer is baked at a temperature in a range from about 60° C. to about 180° C. such as about 60° C. to form the photoresist layer 60 with a thickness in a range from about 20 nm to about 30 nm. In some embodiments, the PAB can be performed in duration for about 60±10 seconds.

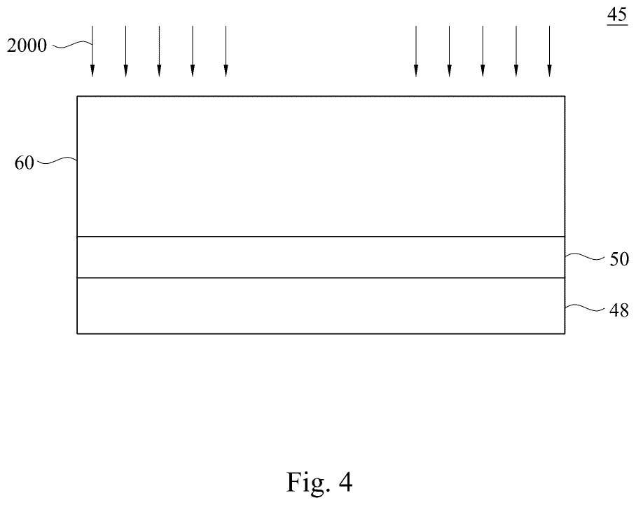

Reference is made to block S206 of FIG. 2 and to FIG. 4. An exposure process 2000 is performed to the photoresist layer 60. In some embodiments, the photoresist layer 60 can be exposed to e-beam, EUV, or the like. As discussed previously with regard to FIG. 3, in some embodiments where the photoresist layer 60 formed by the photoresist composition including the first photoresist and the third photoresist with the formula (a5) is exposed, the photoresist layer 60 can contain SnOₓCl_{y}, in which 2x+y=4, instead of SnO₂. In some other embodiments where the photoresist layer 60 formed by the photoresist composition including the first photoresist and the fourth photoresist with the formula (a6) is exposed, the exposed photoresist layer 60 can contain MₓSn_{y}O_{z} in which M can be a metal such as Zn, Sn, In, or Sc, instead of SnO₂. For example, the exposed photoresist layer 60 can contain ZnₓSn_{y}O_{x+2y}, ScₓSn_{y}O_{3x/2+2y}, InₓSn_{y}O_{3x/2+2y}, SnₓSn_{y}O_{2(x+y)}.

In some embodiments where the photoresist layer 60 includes the first photoresist, the exposure process 2000 can be performed using e-beam with an exposure dose of about 800 μC/cm². such that after a subsequent developing process, the photoresist layer 60 can have a low half pitch (HP) of 19±3 nm. In some embodiments where the photoresist layer 60 includes the first photoresist, the exposure process 2000 can be performed using EUV with an exposure dose of about 50 mJ/cm² to about 60 mJ/cm² such that after a subsequent developing process, the photoresist layer 60 can have a low half pitch (HP) of 20 nm to about 50 nm.

Referring back to block S208 of FIG. 2, a post-exposure bake (PEB) is performed to the photoresist layer 60. For example, the photoresist layer 60 is post-exposure baked at a temperature in a range from about 100° C. to about 180° C., such as about 110° C., for about 60 seconds to about 80 seconds, for example, 60 seconds. In some embodiments, the photoresist layer 60 formed by applying the photoresist composition including the first photoresist can be post-exposure baked at a temperature of about 80±10° C.

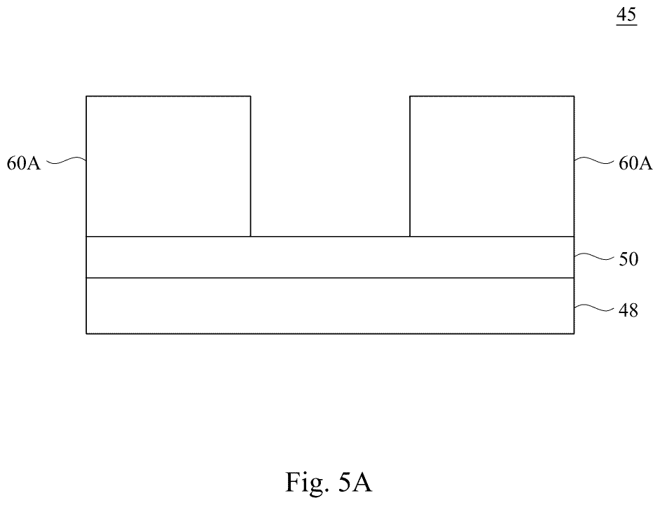

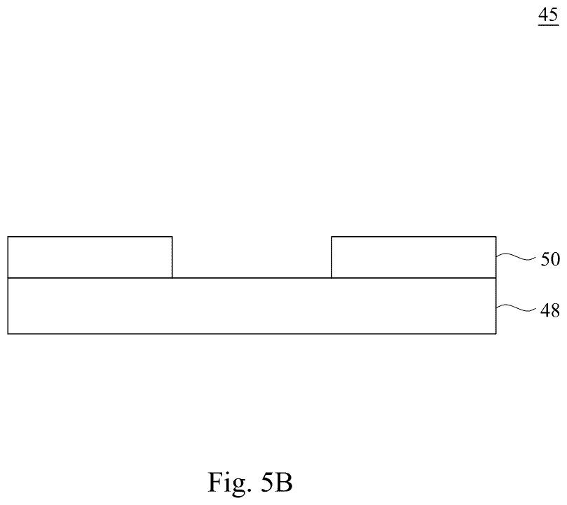

Reference is made to block S210 of FIG. 2 and to FIG. 5A. The photoresist layer 60 is developed, such as using a developer, forming patterned photoresists 60A separated by a recess. In some embodiments where the photoresist layer 60 undergone the e-beam exposure, the first photoresist can provide high resolution e-beam pattern with small e-beam doses. For example, the patterned photoresists 60A can have a low half-pitch (HP), such as about 32±2 nm and a low CD, such as about 37±2 nm with small e-beam doses, such as about 800±50 μC/cm². This patterned photoresist layer 60A can have a low LWR, such as about 3.6±2 nm. In some examples, the patterned photoresists 60A can have a low HP, such as about 19±2 nm and a low CD, such as about 26±2 nm, with small e-beam doses, such as about 800±50 μC/cm². This patterned photoresists 60A can have a low LWR, such as about 4.5±2 nm. In some embodiments where the photoresist layer 60 undergone the EUV exposure, the first photoresist can provide high resolution EUV-beam pattern with small EUV-beam doses. For example, the pattern can have a low HP, such as about 34±2 nm and a low CD, such as about 30±2 nm under low exposure dose of the EUV radiation, such as about 56±10 mJ/cm². In some embodiments, the first photoresist can be Sn₆(C₃H₅)₃(C₄H₉)₃O₄(CH₃CO₂)₅(OH)₅.

Reference is made to block S212 of FIG. 2 and to FIG. 5B. The target layer 50 can be etched by using the patterned photoresists 60A as an etch mask in some embodiments. The patterned photoresists 60A are then removed, for example, by ashing. The ashing operation such as a plasma ash removes the remaining patterned photoresists 60A, and a wet clean may be performed to clean the etch residues.

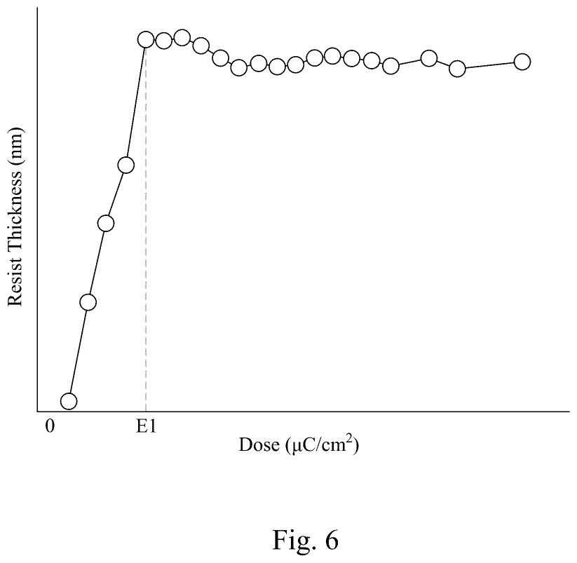

FIG. 6 is a plot with an EUV contrast curve involving a function of exposure dose for the photoresist layer 60 (see FIG. 4) formed by the first photoresist and the second photoresist with the formulae (a3) or (a4). Reference is made to FIGS. 4 and 6. The vertical axis in FIG. 6 refers to a thickness of the photoresist layer 60. The exposure dose E1 of the EUV radiation required for the photoresist layer 60 is in a range from about 300 μC/cm² to about 500 μC/cm², such as about 400 μC/cm².

In some embodiments where the photoresist composition applied to form the photoresist layer 60 includes the first photoresist and the second photoresist with the formula (a3), the patterned photoresists 60A can have a low half-pitch (HP), such as about 22 nm to about 25 nm and a low CD, such as about 26 nm to about 27 nm with small e-beam doses, such as about 800±50 μC/cm². In some embodiments, the first photoresist can be Sn₆(C₃H₅)₆O₄(CH₃COO)₆(OH)₄, the second photoresist can be Sn₆(C₄H₉)₆O₄(OH)₁₀, and a weight ratio of the first photoresist to the second photoresist can be about 1:1.

In some embodiments where the photoresist composition applied to form the photoresist layer 60 includes the first photoresist and the third photoresist with the formula (a5), the patterned photoresists 60A can have a low half-pitch (HP), such as about 20 nm to about 30 nm and a low CD, such as about 25 nm to about 32 nm with small e-beam doses, such as about 1120±50 μC/cm². In some embodiments, the first photoresist can be Sn₆(C₂H₃)₆(C₄H₉COO)₃(OH)₇O₄, the third photoresist can be Sn₆(C₂H₃)₆(C₄H₉COO)₈Cl₂O₄ and the a weight ratio of the first photoresist to the third photoresist is about 2:1. This patterned photoresists 60A can have a low LWR, such as about 3.7 to about 4.7 nm.

In some embodiments where the photoresist composition applied to form the photoresist layer 60 includes the first photoresist and the fourth photoresist with the formula (a6), the patterned photoresists 60A can have a low half-pitch (HP), such as about 15±2 nm and a low CD, such as about 19±2 nm with small e-beam doses, such as about 1760±50 μC/cm². In some embodiments, the first photoresist can be Sn₆(C₄H₉)₆(OH)₁₀O₄, the third photoresist can be Sn(OTf)₂ with a weight ratio of about 10:1. This patterned photoresists 60A can have a low LWR, such as about 8±2 nm.

There are two types of developing processes including a positive tone development (PTD) process and a negative tone development (NTD) process. The PTD process uses a positive tone developer, which generally refers to a developer that selectively dissolves and removes exposed portions of the photoresist layer 60. The NTD process uses a negative tone developer, which generally refers to a developer that selectively dissolves and removes unexposed portions of the photoresist layer 60. In some embodiments, the PTD developers are aqueous base developers, such as tetraalkylammonium hydroxide (TMAH). In some embodiments, the NTD developers are organic-based developers, such as 2-heptanone, a mixture of acetone and hexane, n-butyl acetate (n-BA), acetone, or the like. In some embodiments, a weight ratio of the mixture of acetone and hexane may be in a range from about 1 to about 10, such as 6. In some embodiments, after developing the photoresist layer 60, the patterned photoresists 60A are baked at a temperature in a range from about 80° C. to about 100° C., such as about 90° C.

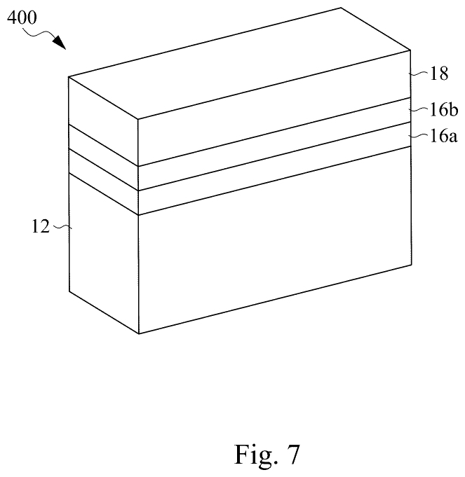

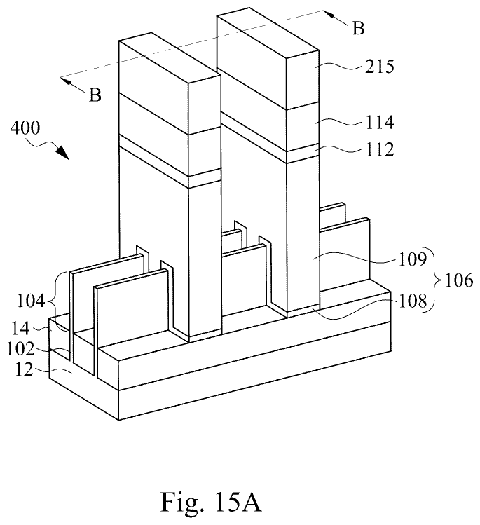

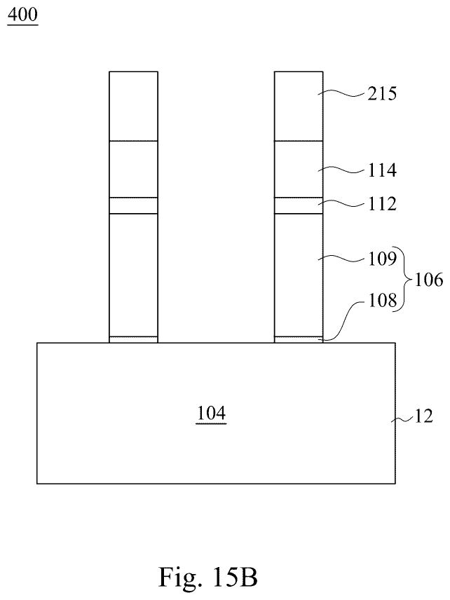

FIGS. 7, 8, 9, 10, 11, 12, 13, 14 and 15A illustrate perspective views of additional fabrication processes in the formation of a semiconductor device 400 in accordance with some embodiments of the present disclosure. FIGS. 15B, 16, 17 and 18 illustrate cross-sectional views of additional fabrication processes in the formation of a semiconductor device 400 in accordance with some embodiments of the present disclosure. Reference is made to FIG. 7. FIG. 7 illustrates a perspective view of an initial structure. The initial structure includes a substrate 12, which is a part of a semiconductor wafer. The substrate 12 is similar to the substrate 48 as discussed previously with regard to FIG. 3 in terms of composition, and its detailed description will be omitted herein. A pad layer 16a and a mask layer 16b may be formed on the substrate 12. The pad layer 16a may be a thin film including silicon oxide formed, for example, using a thermal oxidation process. The pad layer 16a may act as an adhesion layer between the substrate 12 and the mask layer 16b. In some embodiments, the mask layer 16b is formed of silicon nitride, for example, using low-pressure chemical vapor deposition (LPCVD). In other embodiments, the mask layer 16b is formed by thermal nitridation of silicon, plasma enhanced chemical vapor deposition (PECVD), or plasma anodic nitridation. The mask layer 16b is used as a hard mask during a subsequent photolithography process. A photoresist layer 18 may be formed on the mask layer 16b using a spin coating method. The photoresist layer 18 is the same as the photoresist layer 60 as discussed previously with regard to FIG. 3 in terms of composition and formation method, and its detailed description will be omitted herein.

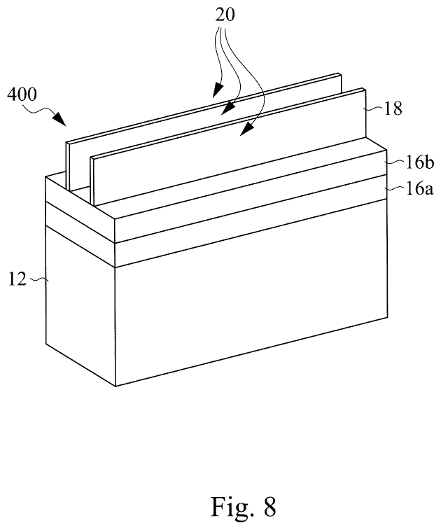

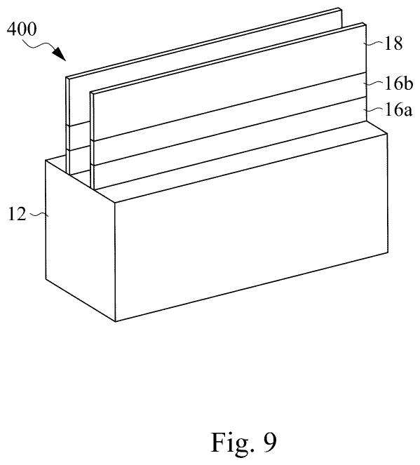

Referring to FIG. 8, the photoresist layer 18 is patterned, forming openings 20 in the photoresist layer 18. The mask layer 16b is thus exposed by the openings 20. Referring to FIG. 9, the mask layer 16b and the pad layer 16a are then etched through the openings 20, exposing the underlying substrate 12.

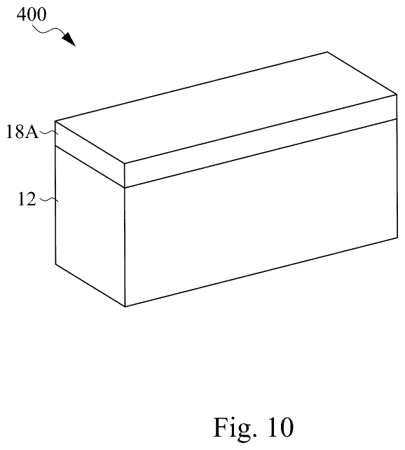

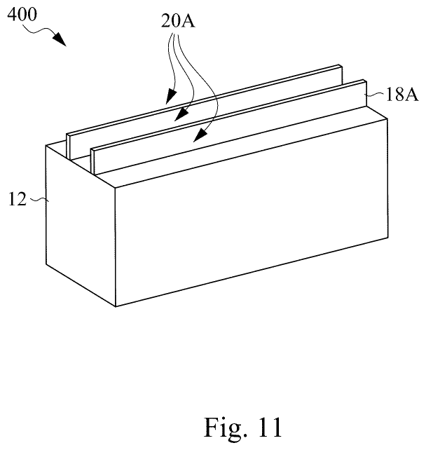

Reference is made to FIG. 10. In some other embodiments, the photoresist layer 18A is formed on the substrate 12 without forming the pad layer 16a and the mask layer 16b (see FIG. 9) prior to forming the photoresist layer 18A. That is, the photoresist layer 18A is in direct contact with the substrate 12. Referring to FIG. 11, the photoresist layer 18A is then patterned, forming openings 20A in the photoresist layer 18A. In some other embodiments, the substrate 12 is etched by a tri-layer resist (not shown), for example, the tri-layer formed by a bottom layer, a middle layer and a top layer. The top layer is made of the composition substantially the same as the composition of the photoresist layer 18. In some embodiments, the bottom layer is a polymer, such as a polymer suitable for forming a bottom anti-reflective coating with no Si content. The composition of the middle layer is chosen such that the middle layer can be selectively etched without substantially etching the bottom layer. In other words, the middle layer and the bottom layer include materials having distinct etching sensitivities towards a given etchant. In some embodiments, the middle layer is a polymer with a higher silicon content than the bottom layer.

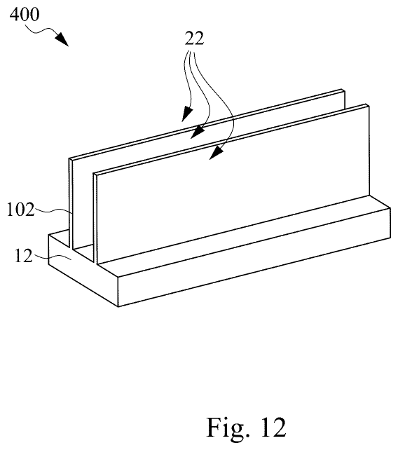

Referring to FIG. 12, the exposed substrate 12 is then etched, forming trenches 22. Portions of the substrate 12 between the neighboring trenches 22 form semiconductor strips 102. The trenches 22 may be strips (when viewed from a top of the substrate 12) that are parallel to each other, and closely located from each other. After etching the substrate 12, the photoresist layer 18 is removed. Next, a cleaning step may be performed to remove native oxide formed on surfaces of the substrate 12. The cleaning may be performed using diluted hydrofluoric (HF) acid, for example.

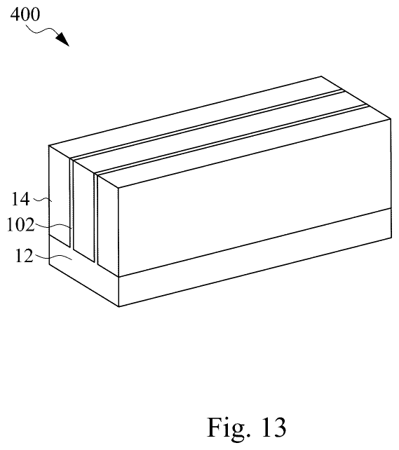

Next, the trenches 22 are filled with a dielectric material using a spin-on method, flowable CVD (FCVD), or the like. In some embodiments, a dielectric liner (not shown) is formed in the trenches 22 prior to forming the dielectric material and may be a conformal layer formed using a deposition technique such as atomic layer deposition (ALD) or the like. A planarization such as chemical mechanical polish (CMP) is then performed to the dielectric material, as shown in FIG. 13, and hence shallow trench isolation (STI) region 14 is formed. In some embodiments, during the planarization, the mask layer 16b and the pad layer 16a, if exist, are removed.

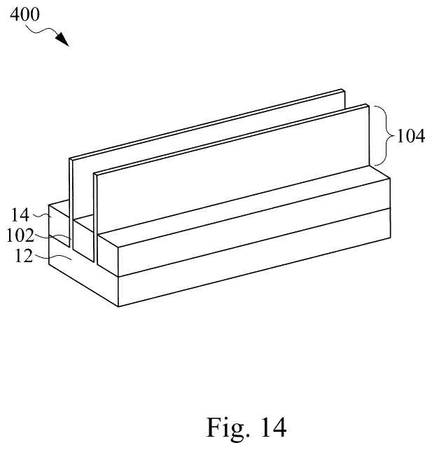

Referring to FIG. 14, the STI regions 14 are recessed, so that top portions of semiconductor strips 102 protrude higher than top surfaces of the neighboring STI regions 14 to form protruding fins 104. The etching may be performed using a dry etching process or a wet etching process.

Referring to FIGS. 15A and 15B, dummy gate structures 106 are formed on the top surfaces and the sidewalls of fins 104. FIG. 15B illustrates a cross-sectional view obtained from a vertical plane containing line B-B in FIG. 15A. Formation of the dummy gate structures 106 includes depositing in sequence a blankly formed gate dielectric layer and a blankly formed dummy gate electrode layer across the fins 104, followed by patterning the blanket formed gate dielectric layer and the blankly formed dummy gate electrode layer. As a result of the patterning, the dummy gate structure 106 includes a dummy gate dielectric layer 108 and a dummy gate electrode 109 over the dummy gate dielectric layer 108. The dummy gate dielectric layers 108 can be any acceptable dielectric layer, such as silicon oxide, silicon nitride, the like, or a combination thereof, and may be formed using any acceptable process, such as thermal oxidation, a spin process, CVD, or the like. The dummy gate electrodes 109 can be any acceptable electrode layer, such as comprising polysilicon, metal, the like, or a combination thereof. The gate electrode layer can be deposited by any acceptable deposition process, such as CVD, plasma enhanced CVD (PECVD), or the like. Each of dummy gate structures 106 crosses over a single one or a plurality of fins 104. The dummy gate structures 106 may have lengthwise directions perpendicular to the lengthwise directions of the respective fins 104.

The blankly formed dummy gate electrode layer and the blankly formed gate dielectric layer may be patterned using a tri-layer structure. Bottom masks 112, top masks 114 and photoresist layers 215 are formed over the blankly formed dummy gate electrode layer in sequence. The photoresist layers 215 may be similar to the patterned photoresist 60A in terms of composition and formation methods as discussed previously with regard to FIGS. 3-5B, and its detailed description will be omitted herein.

In an alternative embodiment, the bottom masks 112 and the top masks 114 are made of one or more layers of SiO₂, SiCN, SiON, Al₂O₃, SiN, or other suitable materials. The bottom masks 112 may be an oxide layer (e.g., silicon oxide) and the top masks 114 may be a nitride (e.g., silicon nitride). The bottom masks 112 and the top masks 114 may be deposited through a process such as CVD, or a spin-on-glass process, although any acceptable process may be utilized.

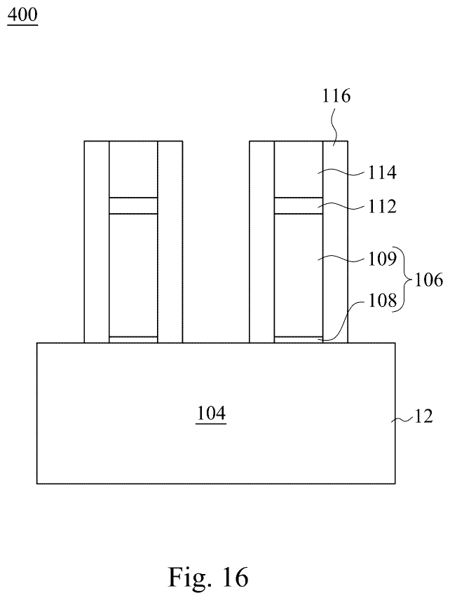

Next, as illustrated in FIG. 16, gate spacers 116 are formed on sidewalls of the dummy gate structures 106. In some embodiments of the gate spacer formation step, a spacer material layer is deposited on the substrate 12. The spacer material layer may be a conformal layer that is subsequently etched back to form gate spacers 116. The spacer material layer is made of a low-k dielectric material. The low-k dielectric material has a dielectric constant (k value) of lower than about 3.5. Suitable materials for the low-k dielectric material may include silicon oxide, silicon nitride, silicon oxynitride, or the like. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate structures 106 (e.g., in source/drain regions of the fins 104). Portions of the spacer material layer directly above the dummy gate structures 106 may be completely removed by this anisotropic etching process. Portions of the spacer material layer on sidewalls of the dummy gate structures 106 may remain, forming gate spacers, which are denoted as the gate spacers 116, for the sake of simplicity. In some embodiments, the gate spacers 116 may be used to offset subsequently formed doped regions, such as source/drain regions. The gate spacers 116 may further be used for designing or modifying the source/drain region profile.

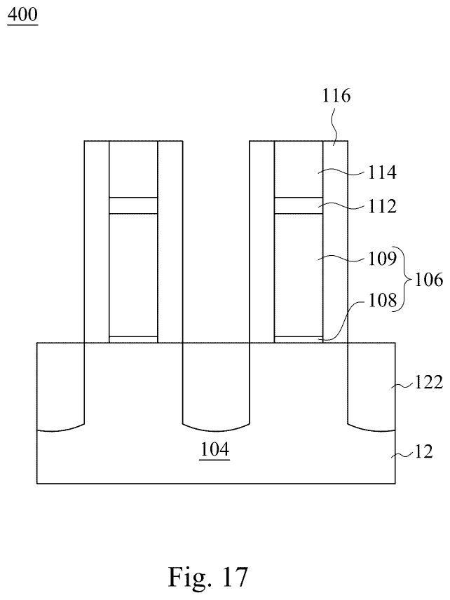

In FIG. 17, after formation of the gate spacers 116 is completed, source/drain epitaxial structures 122 are formed on source/drain regions of the protruding fins 104 that are not covered by the dummy gate structures 106 and the gate spacers 116. In some embodiments, formation of the source/drain epitaxial structures 122 includes recessing source/drain regions of the fin 104, followed by epitaxially growing semiconductor materials in the recessed source/drain regions of the fin 104. The source/drain epitaxial structures 122 are on opposite sides of the dummy gate structure 106.

The source/drain regions of the fins 104 can be recessed using suitable selective etching processing that attacks the fins 104, but hardly attacks the gate spacers 116 and the top masks 114 of the dummy gate structures 106. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 116 and the top masks 114 of the dummy gate structures 106. In some other embodiments, recessing the protruding fins 104 may be performed by a wet chemical etch which etches the fins 104 at a faster etch rate than it etches the gate spacers 116 and the top masks 114 of the dummy gate structures 106. In some other embodiments, recessing the protruding fins 104 may be performed by a combination of a dry chemical etch and a wet chemical etch.

Once recesses are created in the source/drain regions of the fin 104, source/drain epitaxial structures 122 are formed in the source/drain recesses in the fin 104 by using one or more epitaxy or epitaxial (epi) processes that provides one or more epitaxial materials on the protruding fins 104. During the epitaxial growth process, the gate spacers 116 limit the one or more epitaxial materials to source/drain regions in the fin 104. In some embodiments, the lattice constants of the source/drain epitaxial structures 122 are different from the lattice constant of the fins 104, so that the channel region in the fin 104 and between the source/drain epitaxial structures 122 can be strained or stressed by the source/drain epitaxial structures 122 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 122 may include Ge, Si, GaAs, AlGaAs, SiGe, GaAsP, SiP, or other suitable material. The source/drain epitaxial structures 122 may be in-situ doped during the epitaxial process by introducing doping species including p-type dopants, such as boron or BF₂, n-type dopants, such as phosphorus or arsenic, and/or other suitable dopants including combinations thereof. If the source/drain epitaxial structures 122 are not in-situ doped, an implantation process (i.e., a junction implant process) is performed to dope the source/drain epitaxial structures 122. In some exemplary embodiments, the source/drain epitaxial structures 122 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 122 are formed, an annealing process can be performed to activate the p-type dopants or n-type dopants in the source/drain epitaxial structures 122. The annealing process may be, for example, a rapid thermal anneal (RTA), a laser anneal, a millisecond thermal annealing (MSA) process or the like.

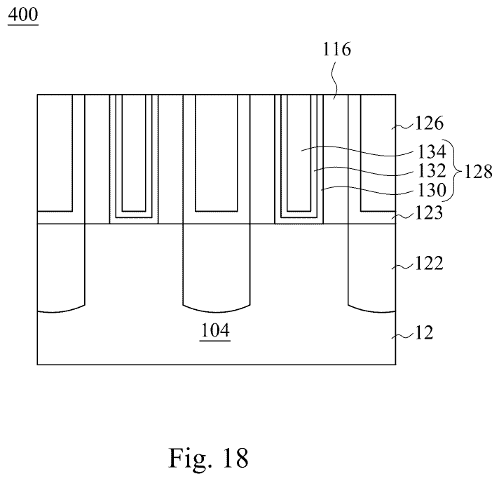

Next, in FIG. 18, a contact etch stop layer (CESL) 123 and an interlayer dielectric (ILD) layer 126 are formed on the substrate 12 in sequence. In some examples, the CESL 123 includes a silicon nitride layer, silicon oxide layer, a silicon oxynitride layer, and/or other suitable materials having a different etch selectivity than the ILD layer 126. The CESL 123 may be formed by plasma-enhanced CVD (PECVD) process and/or other suitable deposition or oxidation processes. In some embodiments, the ILD layer 126 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 123. The ILD layer 126 may be deposited by a PECVD process or other suitable deposition technique. In some embodiments, after formation of the ILD layer 126, the wafer may be subject to a high thermal budget process to anneal the ILD layer 126.

In some examples, after forming the ILD layer 126, a planarization process may be performed to remove excessive materials of the ILD layer 126 and the CESL 123. For example, a planarization process includes a chemical mechanical planarization (CMP) process which removes portions of the ILD layer 126 and the CESL 123 overlying the dummy gate structures 106. In some embodiments, the CMP process also removes bottom masks 112 and top masks 114 (as shown in FIG. 17) and exposes the dummy gate electrodes 109.

An etching process is performed to remove the dummy gate electrode 109 and the dummy gate dielectric layer 108, resulting in gate trenches between corresponding gate spacers 116. The dummy gate structures 106 are removed using a selective etching process (e.g., selective dry etching, selective wet etching, or a combination thereof) that etches materials in the dummy gate structures 106 at a faster etch rate than it etches other materials (e.g., gate spacers 116 and/or the ILD layer 126).

Thereafter, replacement gate structures 128 are respectively formed in the gate trenches. The gate structures 128 may be the final gates of FinFETs. The final gates each may be a high-k/metal gate (HKMG) stack, however, other compositions are possible. In some embodiments, each of the gate structures 128 forms the gate associated with the three-sides of the channel region provided by the fin 104. Stated another way, each of the gate structures 128 wraps around the fin 104 on three sides. In various embodiments, the high-k/metal gate structure 128 includes a gate dielectric layer 130 lining the gate trench, a work function metal layer 132 formed over the gate dielectric layer 130, and a fill metal 134 formed over the work function metal layer 132 and filling a remainder of gate trenches. The gate dielectric layer 130 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (−3.9). The work function metal layer 132 and/or the fill metal 134 used within high-k/metal gate structures 128 may include a metal, metal alloy, or metal silicide. Formation of the high-k/metal gate structures 128 may include multiple deposition processes to form various gate materials, one or more liner layers, and one or more CMP processes to remove excessive gate materials.

In some embodiments, the interfacial layer of the gate dielectric layer 130 may include a dielectric material such as silicon oxide (SiO₂), HfSiO, or silicon oxynitride (SiON). The interfacial layer may be formed by chemical oxidation, thermal oxidation, atomic layer deposition (ALD), CVD, and/or other suitable method. The high-k dielectric layer of the gate dielectric layer 130 may include hafnium oxide (HfO₂). Alternatively, the gate dielectric layer 130 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 132 may include work function metals to provide a suitable work function for the high-k/metal gate structures 128. For an n-type FinFET, the work function metal layer 132 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 132 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 134 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 400 includes other layers or features not specifically illustrated. In some embodiments, back end of line (BEOL) processes are performed on the semiconductor device 400. In some embodiments, the semiconductor device 400 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by applying the novel photoresist composition including the first photoresist having the formula (a1) or the formula (a2) to form the photoresist layer, the photoresist layer can have improved photosensitive property toward the EUV light and the e-beam. Another advantage is that t the photoresist layer can provide low line width roughness (LWR) and low line edge roughness (LER) and high solid content which is with high stability and high stable in air.

In some embodiments, a photoresist composition comprises a first photoresist, wherein the first photoresist has a formula (a1) or a formula (a2):

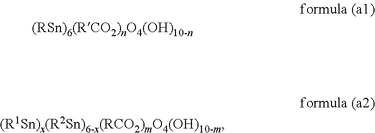

and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e):

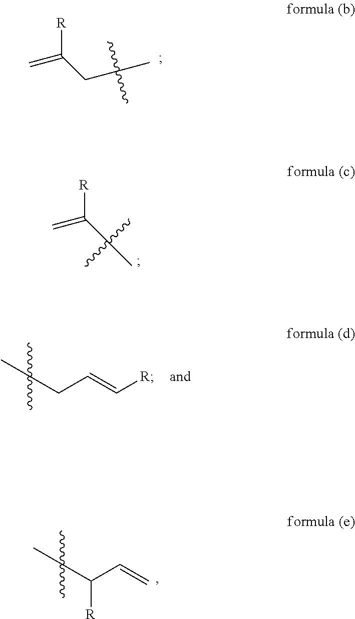

in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6. In some embodiments, the formula (a1) is Sn₆(C₃H₅)₃(C₄H₉)₃O₄(CH₃CO₂)₅(OH)₅. In some embodiments, the formula (a1) is Sn₆(C₂H₃)₆(C₄H₉CO₂)₃(OH)₇O₄. In some embodiments, the photoresist composition further comprises a second photoresist mixed with the first photoresist, wherein the second photoresist has a formula (a3) or a formula (a4):

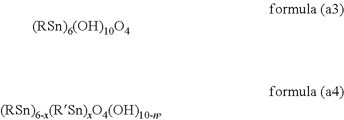

and wherein R in the formula (a3), R and R′ in the formula (a4), individually is H, n-CₙH₂ₙ₊₁, i-CₙH₂ₙ₊₁, t-CₙH₂ₙ₊₁, or one of the formulae (b) to (e), x in the formula (a4) is an integer from 0 to 6. In some embodiments, the formula (a1) is Sn₆(C₃H₅)₆O₄(CH₃COO)₆(OH)₄ and the formula (a3) is (n-BuSn)₆O₄(OH)₁₀. In some embodiments, the photoresist composition further comprises a third photoresist mixed with the first photoresist, wherein the third photoresist has a formula (a5):

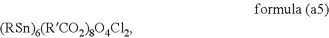

in the formula (a5), each of R and R′ individually is one of formulae (h1) to (h8):

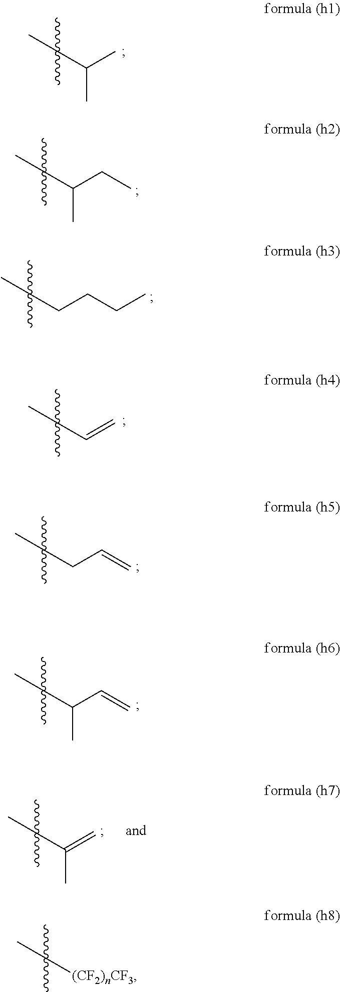

and n in the formula (h8) is 0 to 2. In some embodiments, the formula (a1) is Sn₆(C₂H₃)₆(C₄H₉CO₂)₃(OH)₇O₄ and the formula (a5) is Sn₆(C₂H₃)₆(C₄H₉CO₂)₈Cl₂O₄. In some embodiments, the photoresist composition further comprises a fourth photoresist mixed with the first photoresist, wherein the fourth photoresist has a formula (a6):

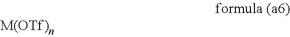

in which M is Zn, Sn, In, or Sc, and n in the formula (a6) is an integer from 1 to 4. In some embodiments, the formula (a1) is Sn₆(C₄H₉)₆(OH)₁₀O₄ and the formula (a6) is Sn(OTf)₂.

In some embodiments, a lithography method comprises the following steps. A target layer is formed over a substrate. A photoresist composition is applied over the target layer to form a photoresist layer, wherein the photoresist composition comprises a first photoresist having a formula (a1) or a formula (a2):

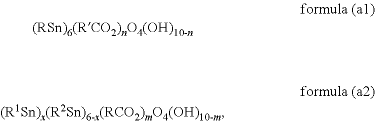

and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e):

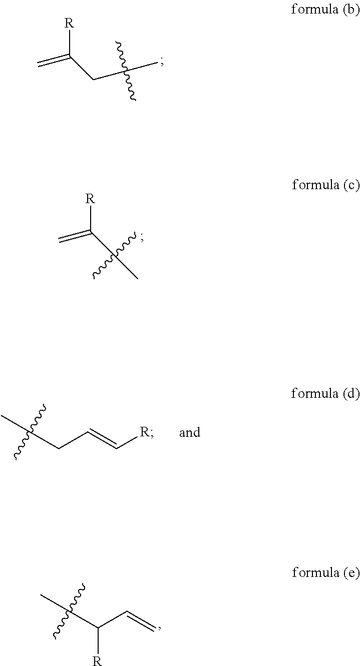

in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6. The photoresist layer is exposed. The photoresist layer is developed. The target layer is etched using the photoresist layer as an etch mask. In some embodiments, the formula (a1) is Sn₆(C₃H₅)₃(C₄H₉)₃O₄(CH₃CO₂)₅(OH)₅. In some embodiments, the formula (a1) is Sn₆(C₂H₃)₆(C₄H₉CO₂)₃(OH)₇O₄. In some embodiments, the lithography method further comprises a second photoresist mixed with the first photoresist, wherein the second photoresist has a formula (a3) or a formula (a4):

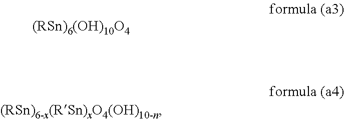

and wherein R in the formula (a3), R and R′ in the formula (a4), individually is H, n-CₙH₂ₙ₊₁, i-CₙH₂ₙ₊₁, t-CₙH₂ₙ₊₁, or one of the formulae (b) to (e). In some embodiments, the lithography method further comprises a third photoresist mixed with the first photoresist, wherein the third photoresist has a formula (a5):

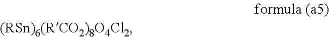

in the formula (a5), each of R and R′ individually is one of formulae (h1) to (h8):

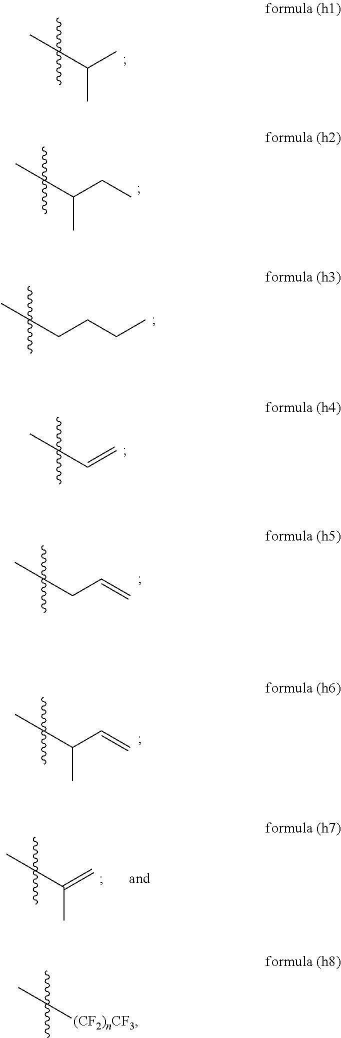

and n in the formula (h8) is 0 to 2. In some embodiments, after exposing the photoresist layer, the photoresist layer comprises SnOₓCl_{y}, in which 2x+y=4. In some embodiments, the lithography method further comprises a fourth photoresist mixed with the first photoresist, wherein the fourth photoresist has a formula (a6):

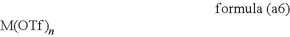

in which M is Zn, Sn, In, or Sc, and n in the formula (a6) is an integer from 1 to 4. In some embodiments, after exposing the photoresist layer, the photoresist layer comprises MₓSn_{y}O_{z}. In some embodiments, the lithography method further comprises a metal triflate salt mixed with the first photoresist.

In some embodiments, an extreme ultraviolet lithography (EUVL) method comprises the following steps. A droplet generator is turned on to eject a metal droplet toward a zone of excitation in front of a collector. A laser source is turned on to emit a laser toward the zone of excitation, such that the metal droplet is heated by the laser to generate EUV radiation. The EUV radiation is guided, by using one or more first optics, toward a reflective mask in an exposure device. The EUV radiation is guided, by using one or more second optics, reflected from the reflective mask toward a photoresist layer coated substrate in the exposure device. The photoresist layer is formed by applying a photoresist composition comprising a first photoresist, the first photoresist has a formula (a1) or formula (a2):

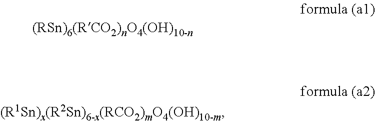

and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e):

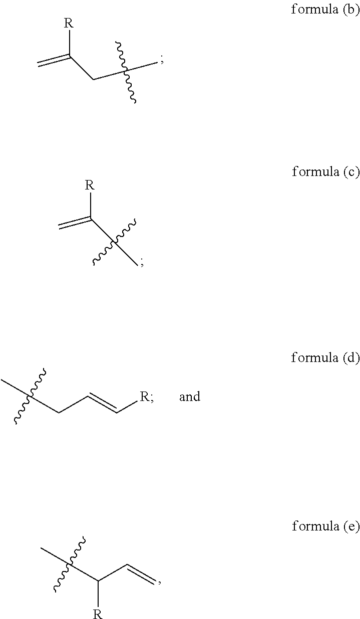

in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6. In some embodiments, the photoresist composition further comprises a second photoresist mixed with the first photoresist, and the second photoresist comprises a metal triflate salt.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist composition, comprising:
a first photoresist, wherein the first photoresist has a formula (a1) or a formula (a2): 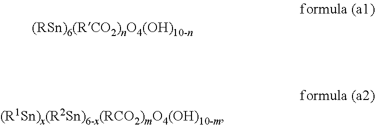
and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e): 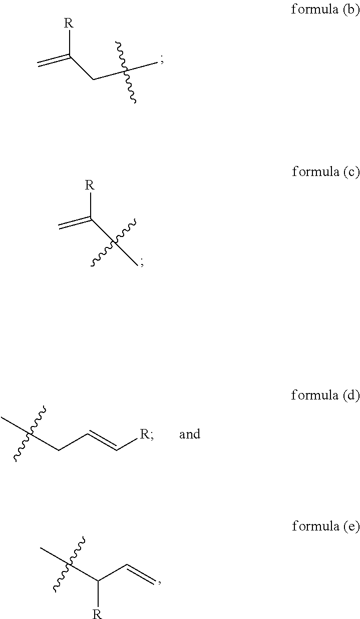
in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6.

2. The photoresist composition of claim 1, wherein the formula (a1) is

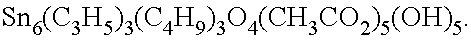

3. The photoresist composition of claim 1, wherein the formula (a1) is

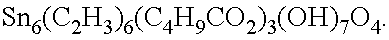

4. The photoresist composition of claim 1, further comprising:
a second photoresist mixed with the first photoresist, wherein the second photoresist has a formula (a3) or a formula (a4): 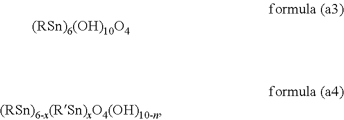
and wherein R in the formula (a3), R and R′ in the formula (a4), individually is H, n-CₙH₂ₙ₊₁, i-CₙH₂ₙ₊₁, t-CₙH₂ₙ₊₁, or one of the formulae (b) to (e), x in the formula (a4) is an integer from 0 to 6.

5. The photoresist composition of claim 4, wherein the formula (a1) is Sn₆(C₃H₅)₆O₄(CH₃COO)₆(OH)₄ and the formula (a3) is (n-BuSn)₆O₄(OH)₁₀.

6. The photoresist composition of claim 1, further comprising:
a third photoresist mixed with the first photoresist, wherein the third photoresist has a formula (a5): 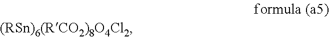
in the formula (a5), each of R and R′ individually is one of formulae (h1) to (h8): 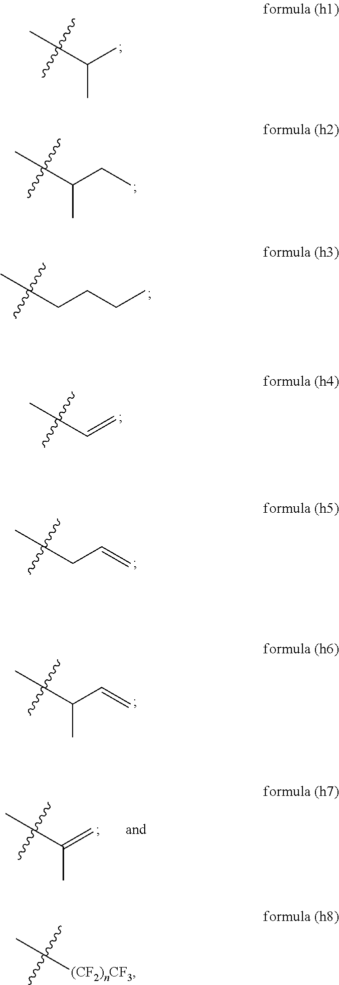
and n in the formula (h8) is 0 to 2.

7. The photoresist composition of claim 6, wherein the formula (a1) is Sn₆(C₂H₃)₆(C₄H₉CO₂)₃(OH)₇O₄ and the formula (a5) is Sn₆(C₂H₃)₆(C₄H₉CO₂)₈Cl₂O₄.

8. The photoresist composition of claim 1, further comprising:
a fourth photoresist mixed with the first photoresist, wherein the fourth photoresist has a formula (a6):
M(OTf)ₙ formula (a6) in which M is Zn, Sn, In, or Sc, and n in the formula (a6) is an integer from 1 to 4.

9. The photoresist composition of claim 8, wherein the formula (a1) is Sn₆(C₄H₉)₆(OH)₁₀O₄ and the formula (a6) is Sn(OTf)₂.

10. A lithography method, comprising:
forming a target layer over a substrate;
applying a photoresist composition over the target layer to form a photoresist layer, wherein the photoresist composition comprises a first photoresist having a formula (a1) or a formula (a2): 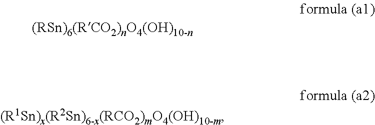
and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e): 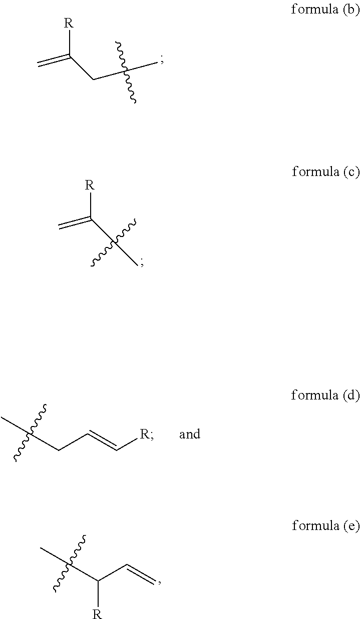
in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6;
exposing the photoresist layer;
developing the photoresist layer; and
etching the target layer using the photoresist layer as an etch mask.

11. The lithography method of claim 10, wherein the formula (a1) is

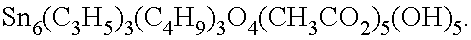

12. The lithography method of claim 10, wherein the formula (a1) is

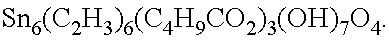

13. The lithography method of claim 10, further comprising:
a second photoresist mixed with the first photoresist, wherein the second photoresist has a formula (a3) or a formula (a4): 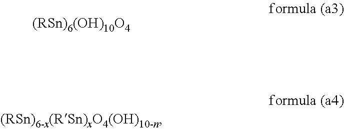
and wherein R in the formula (a3), R and R′ in the formula (a4), individually is H, n-CₙH₂ₙ₊₁, i-CₙH₂ₙ₊₁, t-CₙH₂ₙ₊₁, or one of the formulae (b) to (e).

14. The lithography method of claim 10, further comprising:
a third photoresist mixed with the first photoresist, wherein the third photoresist has a formula (a5):
(RSn)₆(R′CO₂)₈O₄Cl₂ formula (a5), in the formula (a5), each of R and R′ individually is one of formulae (h1) to (h8): 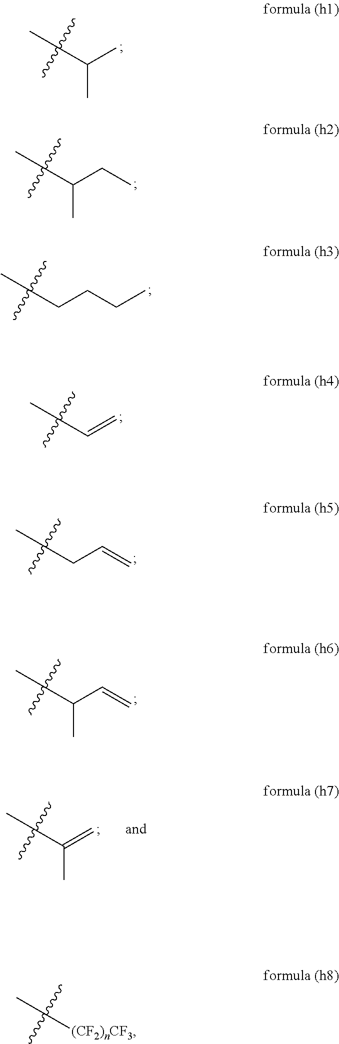
and n in the formula (h8) is 0 to 2.

15. The lithography method of claim 14, wherein after exposing the photoresist layer, the photoresist layer comprises SnOₓCl_{y}, in which 2x+y=4.

16. The lithography method of claim 10, further comprising:
a fourth photoresist mixed with the first photoresist, wherein the fourth photoresist has a formula (a6): 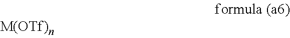
in which M is Zn, Sn, In, or Sc, and n in the formula (a6) is an integer from 1 to 4.

17. The lithography method of claim 16, wherein after exposing the photoresist layer, the photoresist layer comprises MₓSn_{y}O_{z}.

18. The lithography method of claim 10, further comprising:
a metal triflate salt mixed with the first photoresist.

19. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist layer coated substrate in the exposure device, wherein the photoresist layer is formed by applying a photoresist composition comprising a first photoresist, the first photoresist has a formula (a1) or formula (a2): 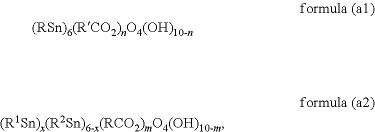
and wherein each of R and R′ in the formula (a1), R¹, R² and R in the formula (a2), individually is H, n-CₙH₂ₙ₊₁, i-CₙH₂ₙ₊₁, or t-CₙH₂ₙ₊₁, or one of formulae (b) to (e): 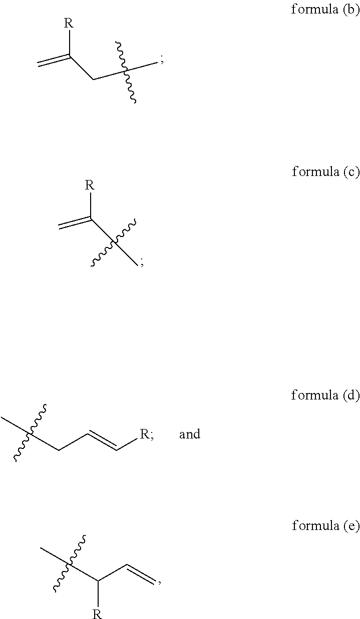
in which R in the formulae (b) to (e) is a moiety including H, n-CₙH₂ₙ₊₁, i-CₙH₂ₙ₊₁, or t-CₙH₂ₙ₊₁, n in the moiety is an integer from 1 to 5, n in the formula (a1) is an integer from 0 to 6, m in the formula (a2) is an integer from 0 to 6, x in the formula (a2) is an integer from 0 to 6.

20. The EUVL method of claim 19, wherein the photoresist composition further comprises a second photoresist mixed with the first photoresist, and the second photoresist comprises a metal triflate salt.
